(19) United States
(12) Patent Application Publication
(10) Pub. No.: US 2026/0164663 A1
(43) Pub. Date: Jun. 11, 2026

(54) SEMICONDUCTOR STORAGE DEVICE

(71) Applicant: Kioxia Corporation, Tokyo (JP)

(72) Inventors: Qianqian XU, Nagoya Aichi (JP); Masaki TSUJI, Yokkaichi Mie (JP)

(21) Appl. No.: 19/318,226

(22) Filed: Sep. 3, 2025

(30) Foreign Application Priority Data
Dec. 6, 2024 (JP) 2024-213874

(51) Int. Cl. H10B 43/35; H10B 43/10; H10B 43/27

(52) U.S. Cl. CPC H10B 43/35; H10B 43/10; H10B 43/27

(57) ABSTRACT

According to one embodiment, a semiconductor storage device includes a stacked body of conductive layers and insulation layers. The conductive layers comprise molybdenum. A semiconductor layer extends in a first direction through the stacked body. A first insulation layer is between the stacked body and the semiconductor layer. A charge storage layer is between the stacked body and the first insulation layer. A second insulation layer is between the stacked body and the charge storage layer. A third insulation layer has a first part and a second part. The first part is between a conductive layer and the second insulation layer. The second part is between the conductive layer and an insulation layer. A hafnium oxide layer is between the conductive layer and the third insulation layer. A nitride layer is between the conductive layer and the hafnium oxide layer.

### CROSS-REFERENCE TO RELATED APPLICATIONS

This application is based upon and claims the benefit of priority from Japanese Patent Application No. 2024-213874, filed Dec. 6, 2024, the entire contents of which are incorporated herein by reference.

### FIELD

Embodiments described herein relate generally to a semiconductor storage device.

### BACKGROUND

For a three-dimensional nonvolatile memory in which memory cells are stacked on a semiconductor substrate, it is important to ensure high reliability.

### BRIEF DESCRIPTION OF THE DRAWINGS

FIG. 1 is a diagram schematically depicting aspects of planar layout of a semiconductor storage device according to a first embodiment.

FIG. 2 is a cross-sectional view of a semiconductor storage device according to a first embodiment taken along line A-A in FIG. 1.

FIG. 3 is a cross-sectional view schematically depicting aspects of a pillar structure and a partition structure of a semiconductor storage device according to a first embodiment.

FIG. 4 is another cross-sectional view depicting aspects of a pillar structure and a partition structure of a semiconductor storage device according to a first embodiment.

FIG. 5 depicts aspects of a semiconductor storage device according to a first embodiment.

FIGS. 6A, 6B, and 6C depict aspects of a method for manufacturing a semiconductor storage device according to a first embodiment.

FIG. 7 depicts s aspects of a configuration of a semiconductor storage device according to a first comparative example.

FIG. 8 depicts aspects of a configuration of a semiconductor storage device according to a second comparative example.

FIG. 9 depicts aspects of a semiconductor storage device according to a second embodiment.

FIGS. 10A and 10B depict aspects of a method for manufacturing a semiconductor storage device according to a second embodiment.

### DETAILED DESCRIPTION

It is an object to provide a semiconductor storage device that can ensure high reliability in operation.

In general, according to one embodiment, a semiconductor storage device includes a stacked body of conductive layers and insulation layers alternately stacked in a first direction, the conductive layers comprising molybdenum; a semiconductor layer extending along the first direction in the stacked body; a first insulation layer between the stacked body and the semiconductor layer; a charge storage layer between the stacked body and the first insulation layer; a second insulation layer between the stacked body and the charge storage layer; a third insulation layer including a first part and a second part, the first part being between a conductive layer and the second insulation layer, the second part being between the conductive layer and an insulation layer, the second part being connected to the first part; a first layer between the conductive layer and the third insulation layer, the first layer comprising hafnium oxide; and a second layer between the conductive layer and the first layer, the second layer comprising a nitride. In some examples, the second layer may be between the first layer and the third insulation layer.

Hereinafter, certain example embodiments according to the present disclosure will be described with reference to drawings. These example embodiments are not intended to limit the present disclosure. The drawings are schematic or conceptual, and ratios, dimensions, sizes and the like of respective parts necessarily the same as the actual values thereof. In the specification and the drawings, components are marked with the same reference symbols when substantially the same as one another, and a detailed description of repeated components may be omitted as appropriate.

### First Embodiment

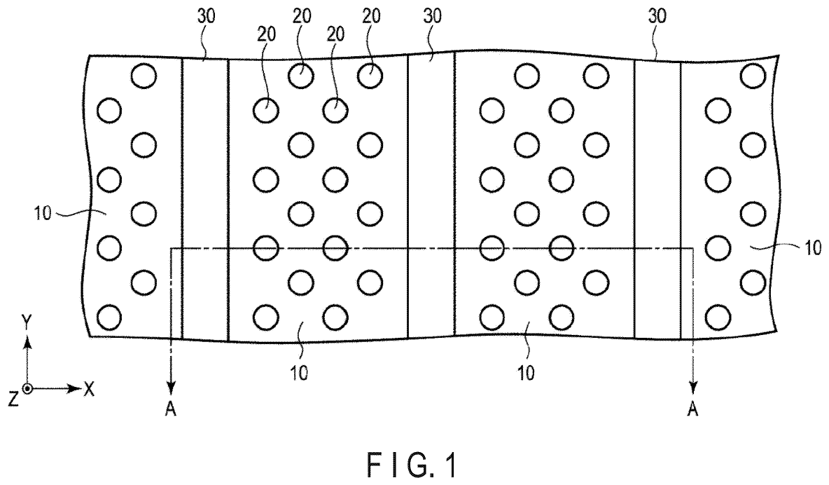

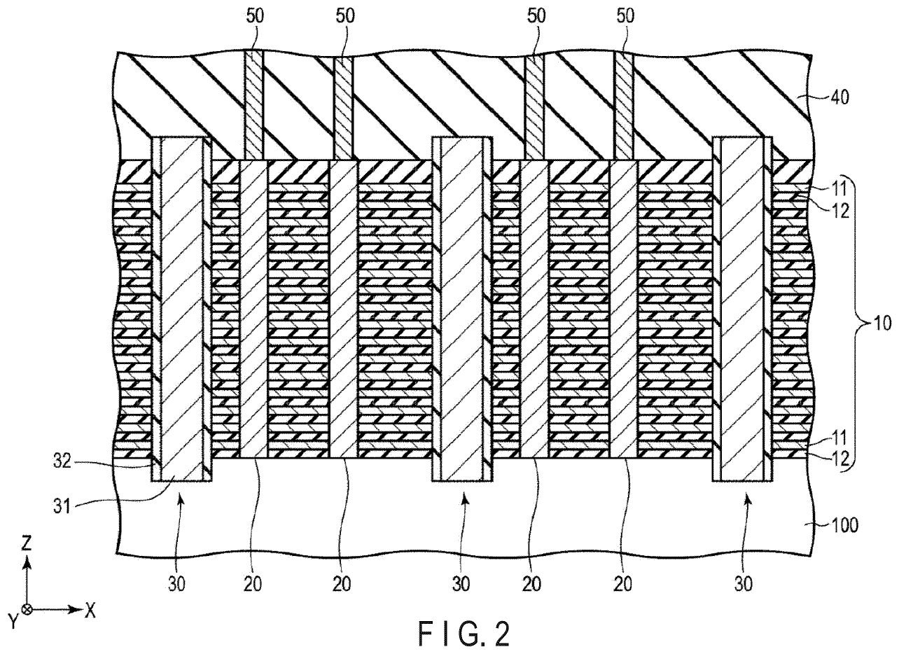

FIG. 1 is a diagram schematically showing a plane pattern of the basic configuration of a semiconductor storage device (NAND-type nonvolatile semiconductor storage device) according to a first embodiment. FIG. 2 is a cross-sectional view taken along line A-A in FIG. 1.

As shown in FIG. 1 and FIG. 2, the semiconductor storage device according to the first embodiment includes a stacked body 10, a plurality of pillar structures 20, a plurality of partition structures 30, an interlayer insulation layer 40, and a plurality of contacts 50.

The stacked body 10 is provided on a semiconductor substrate 100 and has a structure in which a plurality of conductive layers 11 and a plurality of insulation layers 12 are alternately stacked in the Z-direction. That is, the plurality of conductive layers 11 are stacked in the Z-direction in a spaced-apart manner, and the plurality of conductive layers 11 are electrically insulated from one another by the plurality of insulation layers 12.

The conductive layers 11 are made of molybdenum (Mo). The insulation layers 12 are made of an insulating material, such as a silicon oxide. Both the conductive layers 11 and the insulation layers 12 are provided parallel to an XY plane, which is perpendicular to the Z-direction. The conductive layers 11 serve as electrode layers. To be more specific, each conductive layer 11 serves as a word line or a select gate line.

Each pillar structure 20 extends in the Z-direction in the stacked body 10, and includes a semiconductor layer and a charge storage layer, the semiconductor layer extending in the Z-direction, the charge storage layer surrounding the side surface of the semiconductor layer, and the lower end of the semiconductor layer is connected to a common source region. The well region of the semiconductor substrate 100 may serve as a common source region, or a source line as a common source region may be formed on a substrate via various elements forming a peripheral circuit, a wiring, or the like.

Each pillar structure 20 is surrounded by the plurality of conductive layers 11 and the plurality of insulation layers 12. The pillar structure 20 and the plurality of conductive layers 11 surrounding the pillar structure 20 form a NAND string that includes a plurality of memory cells connected in series, and a plurality of select transistors provided on both sides of the plurality of memory cells, which are connected in series.

To more be specific, the conductive layers 11 surrounding the pillar structure 20 serve as gate electrodes for memory cells and select transistors depending on position. That is, the memory cells are formed by certain conductive layers 11 (serving as the word lines) and the particular portions of the pillar structure 20 surrounded by these conductive layers 11 (the word lines). The select transistors are formed by certain conductive layers 11 (serving as the select gate lines) and the particular portions of the pillar structure 20 surrounded by these conductive layers 11 (the select gate lines).

Each partition structure 30 extends in the stacked body 10 in the Y-direction and the Z-direction. The partition structures 30 divide the stacked body 10 into a plurality of portions in the X-direction. This division partitions the pillar structures 20 into a plurality of groups along the X-direction. The partition structures 30 are arranged at substantially equal intervals in the X-direction, and the number of pillar structures 20 arranged between the adjacent partition structures 30 is constant for each group. Each region obtained by dividing the stacked body 10 with the partition structures 30 forms one block. The blocks are a unit of data erase, for example. That is, data in the memory cells of a block can be erased at the same time (same erase operation).

The partition structure 30 includes a conductive part 31 and an insulation part 32. The conductive part 31 is formed by filling a slit used in a replacement processing (described later) with material. The conductive part 31 is made of a conductive material. The insulation part 32 is made of an insulating material. The lower end of the conductive part 31, for example, is connected to the common source region of the semiconductor substrate 100 and serves as a source contact. In some examples, the partition structure 30 may be configured such that the conductive material that serves as the source contact is not included, and the slit after the replacement processing may be solely filled with an insulating material in such a case.

The stacked body 10, the pillar structures 20, and the partition structures 30 is covered by the interlayer insulation layer 40. The contacts 50 penetrate through the interlayer insulation layer 40. The lower ends of the contacts 50 are connected to the semiconductor layers in the pillar structures 20. The upper ends of the contacts 50 are connected to a bit line by vias, for example.

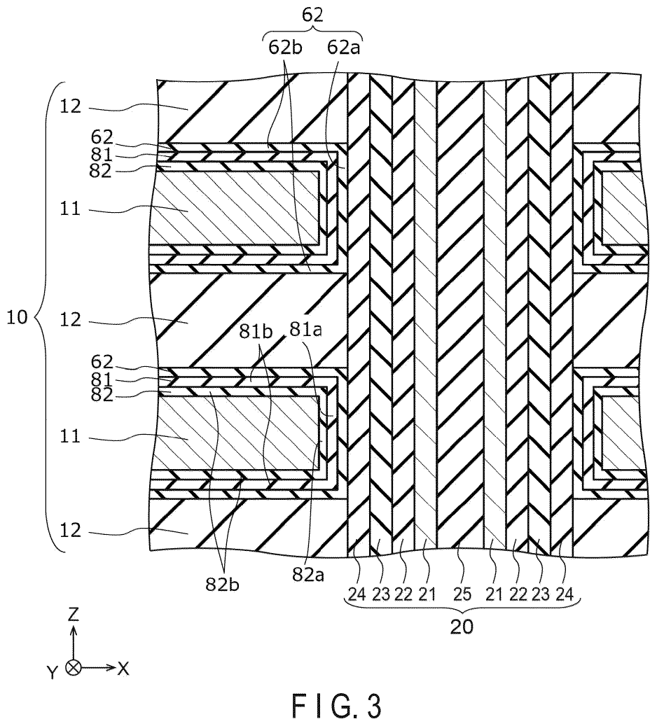

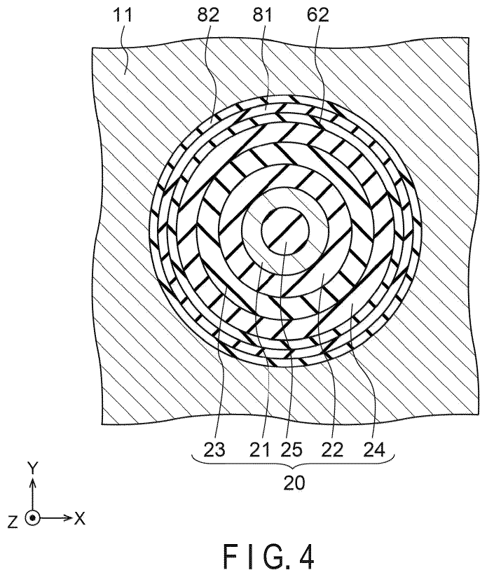

FIG. 3 and FIG. 4 are each a cross-sectional view schematically showing the detailed configuration of a pillar structure 20, and its surroundings. FIG. 3 is a cross-sectional view taken along the direction parallel to the Z-direction, and FIG. 4 is a cross-sectional view taken along the direction perpendicular to the Z-direction.

The pillar structure 20 includes a semiconductor layer 21, a tunnel insulation layer 22, a charge storage layer 23, a block insulation layer 24, and a core insulation layer 25. The semiconductor layer 21, the tunnel insulation layer 22, the charge storage layer 23, and the block insulation layer 24 have cylindrical shapes, and the core insulation layer 25 has a columnar shape. More specifically, the semiconductor layer 21 surrounds the side surface (sidewall) of the core insulation layer 25, the tunnel insulation layer 22 surrounds the side surface of the semiconductor layer 21, the charge storage layer 23 surrounds the side surface of the tunnel insulation layer 22, and the block insulation layer 24 surrounds the side surface of the charge storage layer 23. For example, the semiconductor layer 21 is made of silicon, the tunnel insulation layer 22 is made of silicon oxide, the charge storage layer 23 is made of silicon nitride, the block insulation layer 24 is made of silicon oxide, and the core insulation layer 25 is made of silicon oxide.

A layer 82 is provided on the surface of each conductive layer 11. A layer 81 is provided on the surface of the layer 82. To be more specific, the layer 82 includes a first part 82a and second parts 82b. To be more specific, the layer 81 includes a first part 81a and second parts 81b.

The first part 82a is provided between the pillar structure 20 and the conductive layer 11. The first part 82a is provided along the side surface of the pillar structure 20 and surrounds the side surface of the pillar structure 20. The side surface of the first part 82a is surrounded by the conductive layer 11 and is in contact with the conductive layer 11.

Each second part 82b is provided between a conductive layer 11 and an insulation layer 12. That is, the second parts 82b are provided along the lower surface and the upper surface of the conductive layer 11. Each of the second parts 82b are in contact with one of the lower surface or the upper surface of a conductive layer 11. The second parts 81b are connected to the first part 82a.

The first part 81a is provided between the pillar structure 20 and the conductive layer 11. The first part 81a is provided along the side surface of the pillar structure 20 and surrounds the side surface of the pillar structure 20. The side surface of the first part 81a is surrounded by the first part 82a of the layer 82 and is in contact with the first part 82a of the layer 82.

Each second part 81b is provided between a conductive layer 11 and an insulation layer 12. That is, the second parts 81b are provided along the lower surface and the upper surface of the conductive layer 11. Each of the second parts 81b are in contact with one of the second parts 82b of the layer 82. The second parts 81b are connected to the first part 81a.

Block insulation layers 62 are provided on the outer side of the pillar structure 20. To be more specific, each block insulation layer 62 includes a first part 62a and second parts 62b. The first part 62a is provided between the pillar structure 20 and the conductive layer 11 (a portion provided between the pillar structure 20 and the first part 81a of the layer 81). The second part 62b is provided between the conductive layer 11 and the insulation layer 12 (a portion provided between the second part 81b of the layer 81 and the insulation layer 12). In other words, the first parts 81a, 82a and the second parts 81b, 82b are provided between the conductive layer 11 and the block insulation layer 62. The second parts 62b are connected to the first part 62a.

The block insulation layer 62 is made of, for example, a compound of aluminum (Al) and oxygen (O) (e.g., aluminum oxide, Al₂O₃).

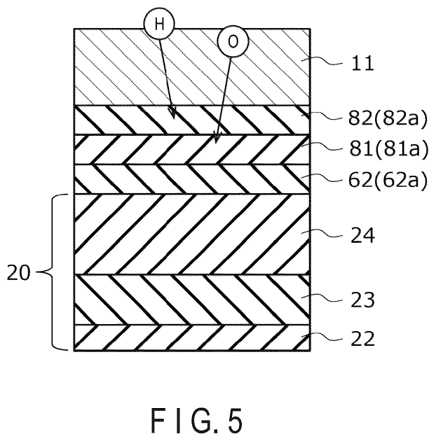

FIG. 5 is a cross-sectional view showing an example of the configuration of the semiconductor storage device according to the first embodiment. FIG. 5 is also an enlarged cross-sectional view showing a region between the pillar structure 20 and the conductive layer 11 in an enlarged manner. FIG. 5 also shows diffusion of oxygen (as an oxygen radical) and hydrogen (as a hydrogen radical).

The layer 81 is provided between the conductive layer 11 and the block insulation layer 62. The layer 81 suppresses the diffusion of oxygen from the conductive layer 11 to the pillar structure 20. Oxygen may be derived from, for example, MoO₂Cl₂ in the film forming (precursor) gas used in forming the conductive layer 11.

The layer 81 comprises a material that can suppress the diffusion of oxygen. The layer 81 is, for example, a metal oxide or a metal nitride. The metal oxide may be hafnium oxide (HfO), for example. The metal oxide is not limited to HfO, and, in other examples, may be aluminum oxide (AlO) or the like. However, when the conductive layer 11 comprise molybdenum (Mo), it is generally preferable that the metal oxide be HfO. An example of a metal nitride is molybdenum nitride (MON).

The layer 82 is provided between the conductive layer 11 and the layer 81. The layer 82 suppresses the diffusion of hydrogen from the conductive layer 11 to the pillar structure 20. Typically, hydrogen is generated in a treatment performed in a post-process step after these deposition steps. The post-process may be, for example, another film formation process or an annealing step.

The layer 82 comprises a material that can suppress the diffusion of hydrogen. For example, the layer 82 includes or comprises a material that reacts with hydrogen, thus reducing the amount of free (diffusing) hydrogen. The layer 82 comprises a nitride, for example. For example, the layer 82 is silicon nitride (SiN).

Although the layer 81 also suppresses the diffusion of hydrogen to some extent, the layer 82 may suppress the diffusion of hydrogen more effectively as compared with the layer 81.

By suppressing both the diffusion of oxygen and the diffusion of hydrogen, it is possible to avoid a situation in which traps are formed in the block insulation layer 24, which causes data retention characteristics to be reduced. By suppressing both the diffusion of oxygen and the diffusion of hydrogen, it is possible to suppress degradation of operating characteristics and to improve reliability of the semiconductor storage device.

Oxygen in the conductive layer 11 diffuses and hence, some portion of oxygen may remain in the conductive layer 11, but other portions enter the layers 81, 82. Hydrogen in the conductive layer 11 diffuse and hence, some portion of the diffused hydrogen may remain in the conductive layer 11, but other portions enter the layers 81, 82. The concentration of hydrogen in the layer 82 may be higher than the concentration of hydrogen in the layer 81. The concentration of oxygen in the layer 81 may be higher than the concentration of oxygen in the layer 82.

The thickness of the layer 81 is approximately 1 nm, for example. The thickness of the layer 82 is substantially equal to, or less than, the thickness of the layer 81. The thickness of the layer 82 is equal to, or less than, 1 nm, for example.

Next, a flow of a manufacturing process will be described.

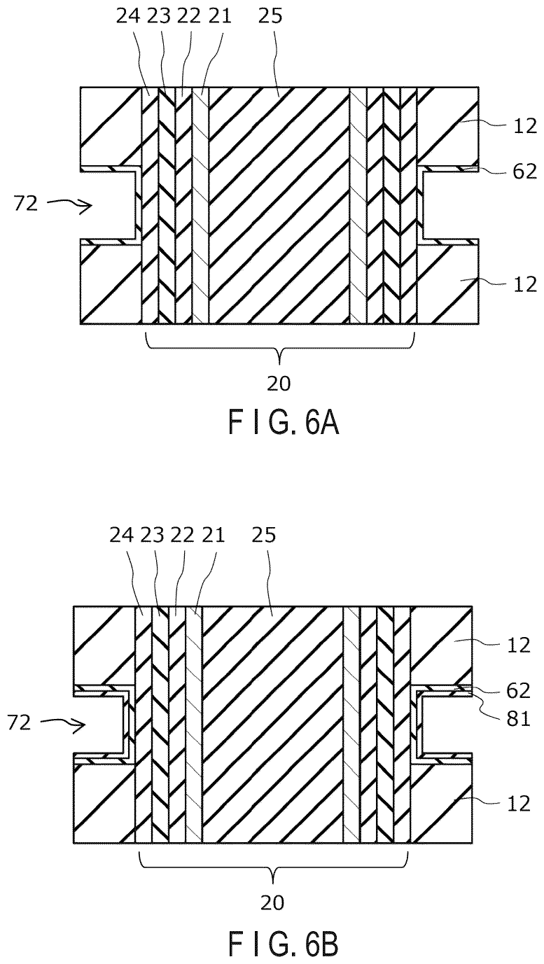

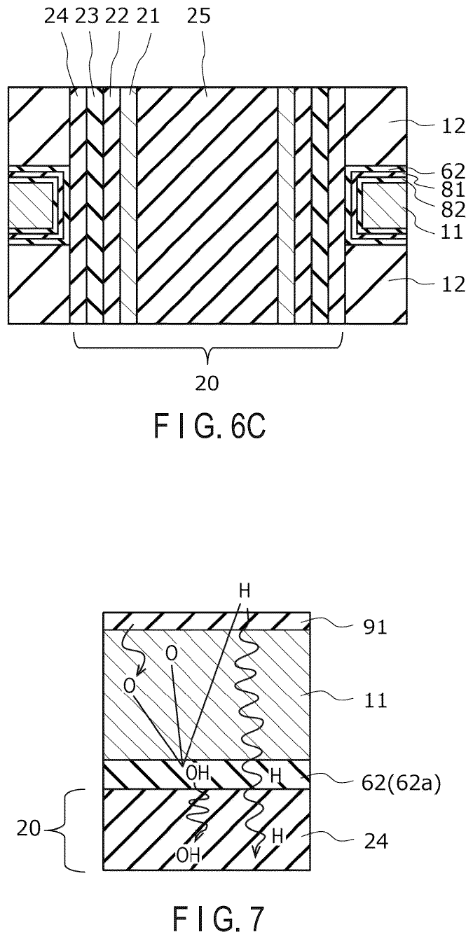

FIG. 6A to FIG. 6C are cross-sectional views showing an example of a method for manufacturing the semiconductor storage device according to the first embodiment.

First, a structure that includes a preliminary stacked body and a pillar structure 20 is formed. The preliminary stacked body has a structure in which a plurality of insulation layers 12 and a plurality of sacrificial layers are alternately stacked in the Z-direction.

Next, the preliminary stacked body is patterned to form slits that penetrate through the preliminary stacked body, and that extend in the Y-direction and the Z-direction.

Next, the sacrificial layers are etched via slits and removed. Consequently, a plurality of hollow areas 72 are formed, each hollow area 72 being provided between adjacent insulation layers 12.

Next, as shown in FIG. 6A, an aluminum oxide (Al₂O₃) layer is formed as a block insulation layer 62 on the surfaces of each slit and each hollow area 72.

Next, as shown in FIG. 6B, a hafnium oxide (HfO) layer is formed (as a layer 81) on the surface of the block insulation layer 62.

Next, as shown in FIG. 6C, a SiN layer is formed (as a layer 82) on the surface of the layer 81. Subsequently, a molybdenum layer is formed as a conductive layer 11 in each hollow area 72 via the slit, the layers 81, 82 and the block insulation layer 62 being formed in in the hollow area 72, and the conductive layer 11 deposited at positions that correspond to the side surfaces of the insulation layers 12 is removed. Then, the layers 81, 82 and the block insulation layer 62 are removed up to the position that corresponds to the side surfaces of the insulation layers 12. Consequently, the first parts 81a, 82a, 62a and the second parts 81b, 82b, 62b of the layers 81, 82 and the block insulation layer 62 are obtained. The sacrificial layers are replaced with the conductive layers 11 (molybdenum layers) in this manner.

A heat treatment may be added before the layer 81 or the layer 82 is formed. Consequently, an increase in warpage or degradation of coverage caused by addition of a layer may be suppressed.

As described above, according to the first embodiment, the layer 81 is provided between the conductive layer 11 and the block insulation layer 62. The layer 81 comprises hafnium oxide (HfO). The layer 82 is provided between the conductive 11 and the layer 81. The layer 82 comprises a nitride. Consequently, it is possible to suppress both the diffusion of oxygen and the diffusion of hydrogen from the conductive layer 11 to the block insulation layer 62. Accordingly, it is possible to avoid a situation in which an increased level of traps is formed in the block insulation layer 24, which reduces data retention characteristics. As a result, it is possible to avoid degradation of characteristics and reliability of the semiconductor storage device.

### Comparative Example

FIG. 7 depicts an example of the configuration of a semiconductor storage device according to a first comparative example. The first comparative example differs from the first embodiment in that the layers 81, 82 are not provided. FIG. 7 also shows diffusion of oxygen and hydrogen.

There are two main possible sources of or causes for diffusion of oxygen from a conductive layer 11 (e.g., a molybdenum layer). The first possible cause is that oxygen in a molybdenum source (precursor) gas (e.g., MoO₂Cl₂) remains mixed into the final molybdenum layer, and this oxygen in the molybdenum layer diffuses out of the layer. The second possible cause is oxygen from an oxide layer 91 formed on the surface of the molybdenum layer that penetrates into the molybdenum layer.

In general, diffusion of hydrogen from the conductive layer 11 is caused by a treatment performed in a post-process.

Due to the diffused oxygen and the diffused hydrogen, OH can be generated in a block insulation layer 62 or a block insulation layer 24, and traps can be formed in the block insulation layer 24. For this reason, there is a possibility that electrons in a charge storage layer 23 will be trapped in the block insulation layer 24, so that data retention characteristics of the charge storage layer 23 are degraded. As a result, a problem occurs in that operating characteristics and reliability of the semiconductor storage device are lowered.

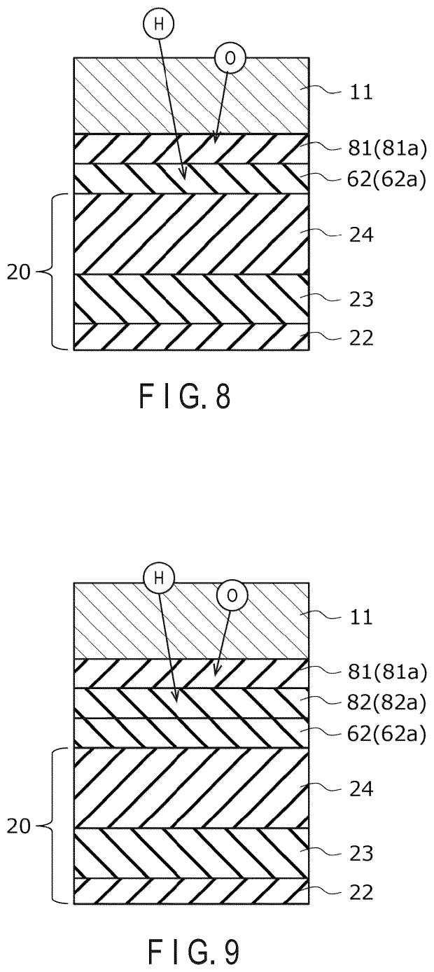

FIG. 8 is a cross-sectional view showing an example of the configuration of a semiconductor storage device according to a second comparative example. The second comparative example differs from the first embodiment in that the layer 82 is not provided.

The diffusion of oxygen can be suppressed by a layer 81. However, hydrogen passes through the layer 81, and diffuses and hence, there is a possibility that OH will be generated in a block insulation layer 62 or a block insulation layer 24.

In contrast, in the first embodiment, the layer 82, which suppresses the diffusion of hydrogen, is provided and hence, it is possible to suppress the generation of OH in both the block insulation layer 62 and the block insulation layer 24. Accordingly, it is possible to suppress a situation in which traps are formed in the block insulation layer 24, and thus data retention characteristics are reduced. As a result, with the inclusion of layer 82, it is possible to suppress degradation of operating characteristics and improve reliability of the semiconductor storage device.

### Second Embodiment

FIG. 9 is a cross-sectional view showing an example of the configuration of a semiconductor storage device according to a second embodiment. The second embodiment differs from the first embodiment in that the position of the layer 81 and the position of the layer 82 are switched (reversed).

A layer 82 is provided between a layer 81 and a block insulation layer 62.

Oxygen in conductive layer 11 diffuses and hence, diffused oxygen may remain in the conductive layer 11 or enter in the layer 81. Hydrogen in the conductive layer 11 diffuses and hence, diffused hydrogen may remain in the conductive layer 11 or enter the layers 81, 82.

Next, a flow of a manufacturing process will be described.

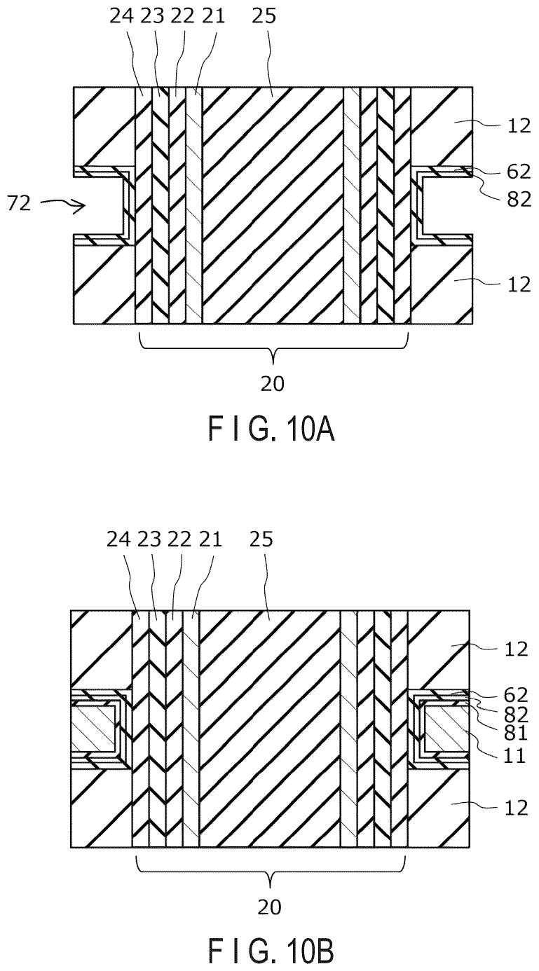

FIG. 10A and FIG. 10B are cross-sectional views showing an example of a method for manufacturing the semiconductor storage device according to the second embodiment. Steps shown in FIG. 10A and FIG. 10B are performed after an initial step shown in FIG. 6A.

An aluminum oxide (Al₂O₃) layer is formed as a block insulation layer 62 (see FIG. 6A) and, thereafter, as shown in FIG. 10A, a SiN layer is formed (as a layer 82) on the surface of the block insulation layer 62.

Next, as shown in FIG. 10B, a HfO layer is formed (as a layer 81) on the surface of the layer 82. Thereafter, a conductive layer 11 is formed in the same manner as the step shown in FIG. 6C.

As in the case of the second embodiment, the position of the layer 81 and the position of the layer 82 may be switched (reversed). The semiconductor storage device according to the second embodiment can obtain advantageous effects substantially equal to the advantageous effects of the first embodiment.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor storage device, comprising:
a stacked body of conductive layers and insulation layers alternately stacked in a first direction, the conductive layers comprising molybdenum;
a semiconductor layer extending along the first direction in the stacked body;
a first insulation layer between the stacked body and the semiconductor layer;
a charge storage layer between the stacked body and the first insulation layer;
a second insulation layer between the stacked body and the charge storage layer;
a third insulation layer including a first part and a second part, the first part being between a conductive layer and the second insulation layer, the second part being between the conductive layer and an insulation layer, the second part being connected to the first part;
a first layer between the conductive layer and the third insulation layer, the first layer comprising hafnium oxide; and
a second layer between the conductive layer and the first layer, the second layer comprising a nitride.

2. The semiconductor storage device of claim 1, wherein the nitride is silicon nitride.

3. The semiconductor storage device of claim 1, wherein a thickness of the second layer is less than or equal to a thickness of the first layer.

4. The semiconductor storage device of claim 1, wherein
the conductive layers comprise oxygen and hydrogen,
the first layer includes oxygen, and
the second layer includes hydrogen.

5. The semiconductor storage device of claim 1, wherein the semiconductor layer is a cylindrical shape.

6. The semiconductor storage device of claim 1, wherein the semiconductor layer is a memory pillar.

7. The semiconductor storage device of claim 1, wherein the conductive layers are molybdenum layers.

8. The semiconductor storage device of claim 7, wherein the insulation layers are silicon oxide layers.

9. The semiconductor storage device of claim 8, wherein the semiconductor layer is a memory pillar.

10. A semiconductor storage device, comprising:
a stacked body of conductive layers and insulation layers alternately stacked in a first direction, the conductive layers comprising molybdenum;
a semiconductor layer extending along the first direction in the stacked body;
a first insulation layer between the stacked body and the semiconductor layer;
a charge storage layer between the stacked body and the first insulation layer;
a second insulation layer between the stacked body and the charge storage layer;
a third insulation layer including a first part and a second part, the first part being between a conductive layer and the second insulation layer, the second part being between the conductive layer and an insulation layer, the second part being connected to the first part;
a first layer between the conductive layer and the third insulation layer, the first layer comprising hafnium oxide; and
a second layer between the first layer and the third insulation layer, the second layer comprising a nitride.

11. The semiconductor storage device of claim 10, wherein the nitride is silicon nitride.

12. The semiconductor storage device of claim 10, wherein a thickness of the second layer is less than or equal to a thickness of the first layer.

13. The semiconductor storage device of claim 10, wherein
the conductive layers comprise oxygen and hydrogen,
the first layer includes oxygen, and
the second layer includes hydrogen.

14. The semiconductor storage device of claim 10, wherein the semiconductor layer is a cylindrical shape.

15. The semiconductor storage device of claim 10, wherein the semiconductor layer is a memory pillar.

16. The semiconductor storage device of claim 10, wherein the conductive layers are molybdenum layers.

17. The semiconductor storage device of claim 16, wherein the insulation layers are silicon oxide layers.

18. The semiconductor storage device of claim 17, wherein the semiconductor layer is a memory pillar.

19. A semiconductor storage device, comprising:
a plurality of conductive layers and a plurality of insulation layers alternately stacked in a first direction of a stacked body, the conductive layers comprising molybdenum;
a semiconductor memory pillar extending along the first direction through the plurality of conductive layers and the plurality of insulation layers;
a first insulation layer between the semiconductor memory pillar and the conductive layers and the insulating layers in a second direction perpendicular to the first direction;
a charge storage layer between the stacked body and the first insulation layer in the second direction;
a second insulation layer between the stacked body and the charge storage layer in the second direction;
a third insulation layer including a first part and a second part, the first part being between a conductive layer in the plurality of conductive layers and the second insulation layer in the second direction, the second part being between the conductive layer and an insulation layer in the plurality of insulation layers in the first direction, the second part being connected to the first part;
a first layer between the conductive layer and the third insulation layer, the first layer comprising hafnium oxide; and
a second layer between the conductive layer and the first layer, the second layer comprising a nitride.
